(19) United States
(12) Patent Application Publication
(10) Pub. No.: US 2023/0276919 A1
(43) Pub. Date: Sep. 7, 2023

(54) THICK FILM PRINTED HEAT SPREADER FOR LOW THERMAL MASS HEATING SOLUTIONS

(71) Applicant: LEXMARK INTERNATIONAL, INC., LEXINGTON, KY (US)

(72) Inventors: RUSSELL EDWARD LUCAS, LEXINGTON, KY (US); JERRY WAYNE SMITH, IRVINE, KY (US)

(21) Appl. No.: 18/116,002

(22) Filed: Mar. 1, 2023

Related U.S. Application Data
(60) Provisional application No. 63/316,606, filed on Mar. 4, 2022.

(51) Int. Cl. A45D 2/00; F28F 21/08; B32B 15/04; B32B 9/04; B32B 9/00

(52) U.S. Cl. CPC A45D 2/001; B32B 9/005; B32B 9/041; B32B 15/043; F28F 21/089; H05B 3/265

(57) ABSTRACT

Methods and apparatus include a hair iron having a ceramic heater between first and second arms movable relative to each other between open and closed positions. The ceramic heater has resistive traces that heat up hair during use upon being connected to a power source. On a side of the ceramic heater opposite the resistive traces, a layer of metal is formed to spread out during use the heat from the resistive traces. The metal may be formed as a single or multiple layers. The composition of the metal can be, representatively, pure or alloys of silver, copper, or aluminum with platinum or palladium. The shape of the metal varies as does its coverage on a surface area of the ceramic heater.

This application claims priority to U.S. Provisional Pat. Application No. 63/316,606, filed Mar. 4, 2022.

### BACKGROUND

### 1. Field of the Invention

The present disclosure relates to a thick-film printed heater for a variety of uses. The heater defines a ceramic substrate having a resistive trace for heating and, on a side opposite the trace, a metal layer thick-film printed on the substrate for spreading heat during use. Embodiments contemplate compositions of the metal and its size, shape, and coverage area. Other embodiments particularly contemplate the heater for use in hair-related appliances, such as such as flat irons, straightening irons, curling irons, crimping irons, etc.

### 2. Description of Related Art

Multiple applications exist for using resistive heaters produced by thick-film printing technology. Such applications include, but are not limited to, small appliance devices such as rice cookers and space heaters, large appliances such as ice makers, water heaters for dishwashers and washing machines, cabin heaters for hybrid and electric vehicles, and personal care products such as hair appliances.

Thick film printed ceramic heaters are typically produced by applying resistor patterns (producing heat when electrical current is applied), conductor patterns (used to connect resistor patterns to an electrical current source), and electrically insulative glass layers onto a ceramic substrate. The layers are applied by forcing an ink or paste through the openings of a mesh screen or stencil, via a squeegee under load. The ceramic substrate can be formed into multiple form factors of various shapes and sizes. Typical ways of forming such substrates include laser scribing via carbon dioxide laser or fiber laser. A great variety of shapes and sizes can be produced using these methods. Thick film printed ceramic heaters are also known as having relatively low thermal mass compared to conventional heaters such as “Calrods,” relatively high ‘withstand temperatures’ compared to film heaters, and relatively high-power density. Of these, relatively low thermal mass affords quick heating and cooling responsiveness in applications in which thick film printed heaters are selected.

However, these heaters are printed with fixed resistor lengths including a temperature measuring device, such as a thermistor, placed at a location near the center of the resistor lengths. During use, thermal gradients develop along the resistor lengths unless the thermal load on the heaters covers the entire length of the resistor. They develop because any resistor portion not receiving the thermal load reaches higher temperatures more quickly in comparison to resistor portions having a thermal load. In turn, a variety of solutions have been proposed to overcome this problem. In laser printers utilizing thick film printed ceramic heaters, for instance, multiple thermistors are positioned along the heater length that are coupled with algorithms that control printer speed to allow recovery from thermal gradient created by narrow media - media which does not cover the entire resistor length(s). In other devices, such as hair irons, power control algorithms have been used to create load-dependent dynamic power control that reduce thermal gradients by restricting power not applied to the task of hair styling. Still other solutions have used positive temperature coefficient (PTC) elements with external heat sinks adhered thereto. While previous solutions have been somewhat effective, the inventors recognize a need for more efficacious solutions. The inventors further note that any solutions in the technology of heaters should further contemplate the competing design constraints found in power consumption, safety features, warm-up characteristics, operating temperatures, heating speeds, thermal conductivity, materials, costs, electrical requirements, construction, materials to-be-heated, temperature control, installation/integration with other components, size, shape, and dimensions, and the like.

### SUMMARY

Methods and apparatus include a ceramic heater for varied uses that have one or more resistive traces that heat up upon being connected to a power source. On a side of the ceramic heater opposite the resistive traces, a layer of metal is formed to spread out heat generated from the resistive traces during use. The metal may be formed as a single or multiple layers. The composition of the metal can be pure or alloys of silver, copper, or aluminum with platinum or palladium, for example. The shape of the metal varies as does its coverage on a surface area of the ceramic heater.

### BRIEF DESCRIPTION OF THE DRAWINGS

The foregoing summary, as well as the following detailed description, is better understood when read in conjunction with the appended drawings. However, the invention is not limited to the specific methods and components disclosed herein. Like numerals represent like features in the drawings. In the views:

FIGS. 1A and 1B show a representative hair iron having a thick-film printed ceramic heater for spreading heat during use;

FIGS. 2A and 2B are views similar to FIGS. 1A and 1B having covers removed to reveal electronic components;

FIG. 3 is a diagrammatic schematic view of a power control system of a hair iron;

FIGS. 4A and 4B are plan views of an inner face and an outer face, respectively, of a ceramic heater for use in a hair iron;

FIG. 5 is a cross-sectional view of the heater shown in FIGS. 4A and 4B taken along line 5-5 in FIG. 4A;

FIGS. 6A-6I are diagrammatic views of a representative sequence of printing, drying, and firing layers on a substrate when forming a heat spreader according to embodiments of the invention;

FIG. 7 is a graph of representative heating profiles according to embodiments of the invention for firing in a heating unit a base or substrate with or without overlying layers; and

FIGS. 8A-8E are diagrammatic views of alternate embodiments of thick-film printed ceramic heaters for spreading out heat during use.

### DETAILED DESCRIPTION

As noted above, the heater of the many embodiments herein finds utility in many and diverse applications. It will be described, however, most particularly in relation to a hair-related appliance, such as a hair iron, but should not be so limited unless specifically claimed.

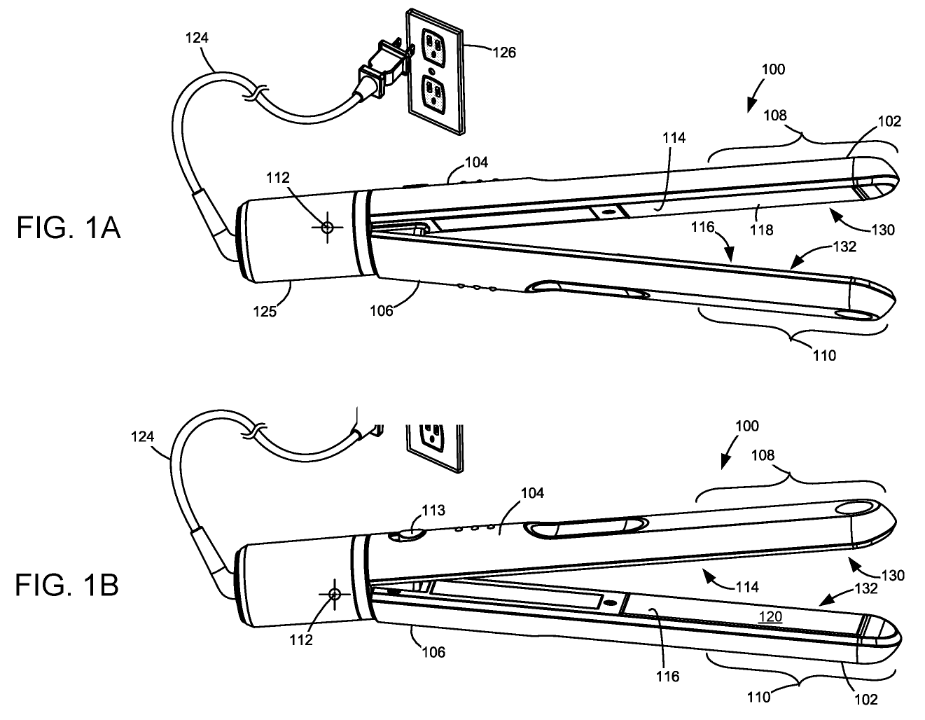

Referring now to the drawings, and particularly to FIGS. 1A and 1B, a hair iron 100 is shown according to an example embodiment. Hair iron 100 includes an appliance such as a flat iron, straightening iron, curling iron, crimping iron, or other similar device that applies heat and pressure to hair in order to change the structure or appearance of the hair. Hair iron 100 has a housing 102 that forms the overall support structure of hair iron 100. The housing 102 may be composed of, for example, a plastic that is thermally insulative and electrically insulative and that possesses relatively high heat resistivity and dimensional stability and low thermal mass. Example plastics include polybutylene terephthalate (PBT) plastics, polycarbonate/acrylonitrile butadiene styrene (PC/ABS) plastics, polyethylene terephthalate (PET) plastics, including glass-filled versions of each. In addition to forming the overall support structure of hair iron 100, the housing 102 also provides electrical insulation and thermal insulation in order to provide a safe surface for the user to contact and hold during operation of hair iron 100.

Hair iron 100 further includes a pair of longitudinally extending arms 104, 106 that are movable between an open and closed position. Distal segments 108, 110 of arms 104, 106 are spaced apart from each other in the open position and are in contact, or close proximity with one another in the closed position. The arms clamshell or are pivotable relative to each other about a pivot axis 112 between the open position and the closed positions. Hair iron 100 may include a bias member (not shown), such as one or more springs, that biases one or both of arms 104, 106 toward the open position such that user actuation is required to overcome the bias applied to arms 104, 106 to bring arms 104, 106 together to the closed position. A lock 113 is provided to secure the arms in the closed position upon user manipulation.

Hair iron 100 includes a heater positioned on an inner side 114, 116 of one or both of arms 104, 106. Inner sides 114, 116 of arms 104, 106 include the portions of arms 104, 106 that face each other when arms 104, 106 are in the open and closed positions. In the example embodiment illustrated, each arm 104, 106 includes a respective heater 130, 132 opposed to one another on or within the arm 104, 106. Heaters 130, 132 supply heat to respective contact surfaces 118, 120 on arms 104, 106. Each contact surface 118, 120 is positioned on inner side 114, 116 of distal segment 108, 110 of the corresponding arm 104, 106. Contact surfaces 118, 120 may be formed directly by a surface of each heater 130, 132 or formed by a material covering each heater 130, 132, such as a shield or sleeve. Contact surfaces 118, 120 are positioned to directly contact and transfer heat to hair upon a user positioning hair between arms 104, 106 during use. Contact surfaces 118, 120 are positioned to mate against one another in a relatively flat orientation when arms 104, 106 are in the closed position in order to maximize the surface area available for contacting hair.

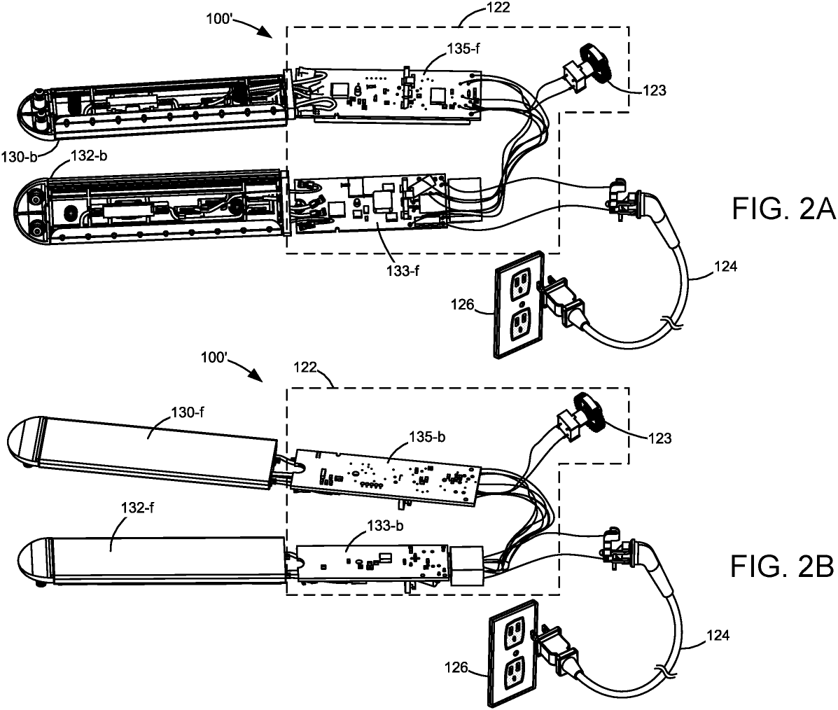

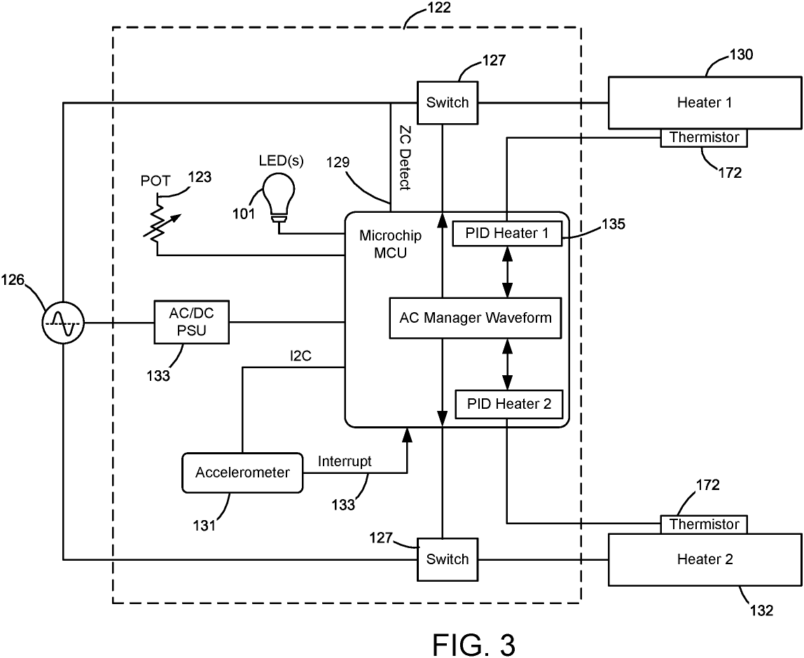

With reference to FIGS. 2A and 2B, hair iron 100′ (as seen in partial disassembled form) includes control circuitry 122 configured to control the power, thus the temperature, of each heater 130, 132. The control circuitry 122 in this design is bifurcated in the two arms of the hair iron, including a printed circuit board 133, 135 having a front (-f) and back (-b) sides. The PCB boards 133, 135 respectively relate to electrical circuit components for a power supply unit (PSU) and a microcontroller unit (MCU) that coordinate to selectively apply electrical current to the heaters 130, 132 (shown schematically in FIG. 3). The hair iron 100 further includes a power cord 124 for connecting hair iron 100 to an external line power or voltage source 126 to power the control circuitry 122 and heaters 130, 132. Amongst different geographies, the line power 126 is typically 115 VAC or 230 VAC.

With reference to FIG. 3, the regulation of line power 126 to the heaters 130, 132, includes control circuitry 122. A potentiometer 123 receives input from a user by twisting a handle 125 (FIG. 1A) of hair iron 100. The settings are varied, but twists of the handle generally relate to the hair iron 100 being off or powered on, with settings for fine, medium, thick, and coarse hair, corresponding to voltages of about 155° C., 175° C., 195° C., and 210° C. to heat the heaters 130, 132. A light emitting diode (LED) 101 indicates to the user whether or not the hair iron 100 is powered on or off. Other settings are possible. One or more triacs or switches 127 connect the heaters 130, 132 to line power 126 under control of the MCU 135. The MCU turns on the triacs 127 when the AC voltage of the line power is at or near a zero-crossing (ZC) as provided on a zero-crossing detection circuit supplied at 129 to the MCU. An accelerometer 131 detects manipulation of the hair iron 100 and the MCU will stop heating of the heaters 130, 132 regardless of the potentiometer 123 setting if the MCU does not receive any interrupts 133 per a given period of time, say every 60 seconds. In this way, the controller knows that a user is manipulating the hair iron for use and not merely setting it aside. The thermistors 172 gather current temperature readings of the heaters 130, 132 that the MCU uses to control the set-points, temperature increases, temperature decreases, and the like, of the heaters. The thermistors provide input to the MCU per a given period of time, such as per every 1 msec. Line voltage varies per geography, e.g., 115 VAC or 230 VAC, and such is read by the MCU through a resistive divider circuit for controlling the power to the heaters. During use, based on the temperature difference of the measured heater temperature by the thermistor and the setpoint temperature, the PID (proportional-integral-derivative) controller calculates a desired temperature response to the current temperature to set the required heating power for each heater. The AC Manager Waveform stores pre-selected profiles of AC power, such that the controller generally adjusts PID gains in a manner to minimize warm up time, reduce ramp up temperature overshoot, and achieve tight steady state temperature control under load-dependent conditions.

Appreciating that the heaters 130, 132 are two independent heating elements of equal resistance and each has a current temperature feedback mechanism by way of the thermistor 172 to the controller 135, during use, the controller activates the switch 127 to control AC power delivery to the heaters. Using the AC zero-crossing (ZC) feedback 129, the power delivery is synchronized precisely with the zero-crossings of the AC mains voltage waveform. This establishes the minimum unit of power delivery as a single half-cycle of the AC sinusoidal waveform. The controller modulates the current of each heater to achieve a desired temperature. This action is moderated by a temperature control loop (e.g., PID) running on the controller. That is, the control loop calculates a desired temperature response by way of a power level in units of percent, where 100% is equal to rated wattage of the heater. The fundamental period of heater power delivery in the following embodiments is based on half-cycles of AC sinusoidal power, such as eight half-cycles, but other numbers of half-cycles are possible to achieve other percentages of power levels.

In one embodiment, the controller causes the switch to connect heaters to the AC line voltage for an integer number of half-cycles within a given period. To achieve a power level percent (%) of 12.5 % (e.g., ⅛×100%), for example, one AC half-cycle of one-thru-eight total half-cycles of sinusoidal power is turned on to heat the heater. Similarly, to achieve a power level percent of 50%, four AC half-cycles 304 of one-thru-eight total half-cycles of sinusoidal power are turned on to the heat the heater (e.g., 4/8×100%). Similarly, too, all power level percentages of the heaters can be read from a table stored by the AC Manager Waveform, e.g., power level percentages 0%, 12.5%, 25%, 37.5%, 50%, 62.5%, 75%, 87.5%, and 100%. Of course, other percentages are possible.

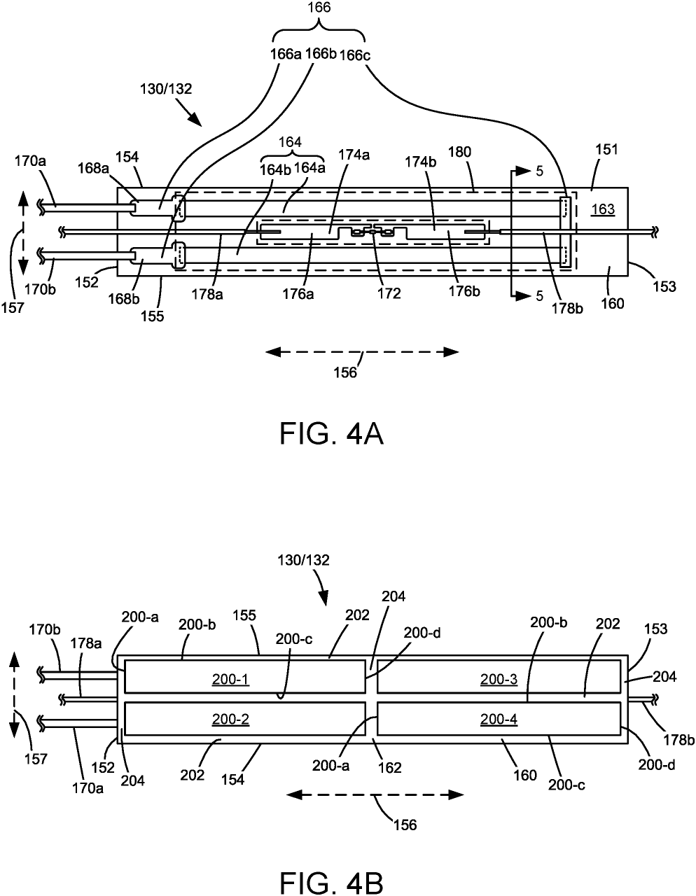

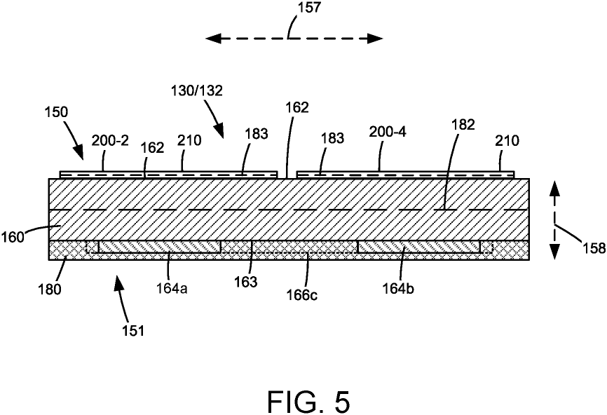

In FIGS. 4A and 4B, heaters 130 or 132 are detailed to show them as removed from their housing. They may or may not be identical to one another. FIG. 4A shows inner face 151 of heater 130/132, and FIG. 4B shows outer face 150 of heater 130/132. In the embodiment illustrated, outer face 150 and inner face 151 are bordered by four sides or edges 152, 153, 154, 155 each having a smaller surface area than outer face 150 and inner face 151. In this embodiment, heater 130/132 includes a longitudinal dimension 156 that extends from edge 152 to edge 153 and a lateral dimension 157 that extends from edge 154 to edge 155. Heater 130/132 also includes an overall thickness 158 (FIG. 5) measured from outer face 150 to inner face 151.

Heater 130/132 includes one or more layers of a ceramic substrate 160, such as aluminum oxide (e.g., commercially available 96% aluminum oxide ceramic). Where heater 130/132 includes a single layer of ceramic substrate 160, a thickness of ceramic substrate 160 may range from, for example, 0.5 mm to 1.5 mm, such as 1.0 mm. Where heater 130 includes multiple layers of ceramic substrate 160, each layer may have a thickness ranging from, for example, 0.5 mm to 1.0 mm, such as 0.635 mm. In some embodiments, a length of ceramic substrate along longitudinal dimension 156 may range from, for example, 80 mm to 120 mm. In some embodiments, a width of ceramic substrate 160 along lateral dimension 157 may range from, for example, 15 mm to 24 mm, such as 17 mm or 22.2 mm. Ceramic substrate 160 includes an outer face 162 that is oriented toward outer face 150 of heater 130/132 and an inner face 163 that is oriented toward inner face 151 of heater 130/132. Outer face 162 and inner face 163 of ceramic substrate 160 are positioned on exterior portions of ceramic substrate 160 such that if more than one layer of ceramic substrate 160 is used, outer face 162 and inner face 163 are positioned on opposed external faces of the ceramic substrate 160 rather than on interior or intermediate layers of ceramic substrate 160. The outer face 162 also includes one or more layers of a metal, such as silver 200 that acts to spread heat over the surface of the ceramic substrate during use. In the embodiment shown, the silver is either pure or alloyed compositions, such as with platinum or palladium, and is layered over the outer face in a thickness of about 10-30 µm, particularly 20-28 µm. It is layered in a coverage amount of the surface area of the ceramic substrate less than 100 % to prevent cracking during thick film printing, drying, and heating. As further seen, the layer of silver is separated by longitudinal and transverse streets 202/204 that separate sides 200-a, -b, -c, -d of the silver from the edges 152, 153, 154, 155 of the substrate. The pattern of the silver 200 may be of nearly an infinite variety, but in this embodiment is shown as four generally rectangular patches having sides generally paralleling the edges of the substrate. Further embodiments of the silver will be described below.

Also, in the example embodiment illustrated, outer face 150 (FIG. 5) of heater 130/132 is formed by outer face 162 of ceramic substrate 160 as shown in FIG. 4B and upper surfaces 210 of the silver (only 200-2, 200-4, shown in this view). Further, in this embodiment, inner face 163 of ceramic substrate 160 includes a series of one or more electrically resistive traces 164 and electrically conductive traces 166 positioned thereon. As is known, the resistive traces heat during use upon application of power from the conductive traces and the silver on a side-opposite thereof acts to spread out the heat generated thereby. In formulation, the resistive traces 164 include a suitable electrical resistor material such as, for example, silver palladium (e.g., blended 70/30 silver palladium). The conductive traces 166 include a suitable electrical conductor material such as, for example, silver platinum. In the embodiment illustrated, resistive traces 164 and conductive traces 166 are applied to ceramic substrate 160 by way of thick film printing. For example, resistive traces 164 may include a resistor paste having a thickness of 10-13 microns when applied to ceramic substrate 160, and conductive traces 166 may include a conductor paste having a thickness of 9-15 microns when applied to ceramic substrate 160. Resistive traces 164 form the heating element of heater 130 and conductive traces 166 provide electrical connections to and between resistive traces 164 in order to supply an electrical current to each resistive trace 164 to generate heat.

In the example embodiment illustrated, heater 130/132 includes a pair of resistive traces 164a, 164b that extend substantially parallel to each other (and substantially parallel to edges 154, 155) along longitudinal dimension 156 of heater 130. Heater 130 also includes a pair of conductive traces 166a, 166b that each form a respective terminal 168a, 168b of heater 130. Cables or wires 170a, 170b are connected to terminals 168a, 168b in order to electrically connect resistive traces 164 and conductive traces 166 to, for example, control circuitry 122 and voltage source 126 in order to selectively close the circuit formed by resistive traces 164 and conductive traces 166 to generate heat. Conductive trace 166a directly contacts resistive trace 164a, and conductive trace 166b directly contacts resistive trace 164b. Conductive traces 166a, 166b are both positioned adjacent to edge 152 in the example embodiment illustrated, but conductive traces 166a, 166b may be positioned in other suitable locations on ceramic substrate 160 as desired. In this embodiment, heater 130/132 includes a third conductive trace 166c that electrically connects resistive trace 164a to resistive trace 164b. Portions of resistive traces 164a, 164b obscured beneath conductive traces 166a, 166b, 166c in FIG. 4A are shown in dotted line. In this embodiment, current input to heater 130/132 at, for example, terminal 168a by way of conductive trace 166a passes through, in order, resistive trace 164a, conductive trace 166c, resistive trace 164b, and conductive trace 164b where it is output from heater 130 at terminal 168b. Current input to heater 130 at terminal 168b travels in reverse along the same path.

In some embodiments, heater 130/132 includes a thermistor 172 positioned in close proximity to a surface of heater 130/132 in order to provide feedback regarding the current temperature of heater 130/132 to control circuitry 122. In some embodiments, thermistor 172 is positioned on inner face 163 of ceramic substrate 160. In the example embodiment illustrated, thermistor 172 is welded directly to inner face 163 of ceramic substrate 160. In this embodiment, heater 130/132 also includes a pair of conductive traces 174a, 174b that are each electrically connected to a respective terminal of thermistor 172 and that each form a respective terminal 176a, 176b. Cables or wires 178a, 178b are connected to terminals 176a, 176b in order to electrically connect thermistor 172 to, for example, control circuitry 122 in order to provide closed loop control of heater 130. In the embodiment illustrated, thermistor 172 is positioned at a central location of inner face 163 of ceramic substrate 160, between resistive traces 164a, 164b and midway from edge 152 to edge 153. In this embodiment, conductive traces 174a, 174b are also positioned between resistive traces 164a, 164b with conductive trace 174a positioned toward edge 152 from thermistor 172 and conductive trace 174b positioned toward edge 153 from thermistor 172. However, thermistor 172 and its corresponding conductive traces 174a, 174b may be positioned in other suitable locations on ceramic substrate 160 so long as they do not interfere with the positioning of resistive traces 164 and conductive traces 166.

FIG. 5 is a cross-sectional view of heater 130/132 taken along line 5-5 in FIG. 4A. With reference to FIGS. 4A, 4B and 5, in the embodiment illustrated, heater 130/132 includes one or more layers of printed glass 180 on inner face 163 of ceramic substrate 160. In the embodiment illustrated, glass 180 covers resistive traces 164a, 164b, conductive trace 166c, and portions of conductive traces 166a, 166b in order to electrically insulate such features to prevent electric shock or arcing. The borders of glass layer 180 are shown in dashed line in FIG. 4A. In this embodiment, glass 180 does not cover thermistor 172 or conductive traces 174a, 174b because the relatively low voltage applied to such features presents a lower risk of electric shock or arcing. An overall thickness of glass 180 may range from, for example, 70-80 microns. FIG. 5 shows glass 180 covering resistive traces 164a, 164b and adjacent portions of ceramic substrate 160 such that glass 180 forms the majority of inner face 151 of heater 130/132. Outer face 162 of ceramic substrate 160 is shown forming outer face 150 of heater 130/132 as discussed above. Conductive trace 166c, which is obscured from view in FIG. 5 by portions of glass 180, is shown in dotted line. FIG. 5 depicts a single layer of ceramic substrate 160. However, ceramic substrate 160 may include multiple layers as depicted by dashed line 182 in FIG. 5. Similarly, the silver may include multiple layers depicted by dashed line 183.

Heater 130/132 may be constructed by way of thick film printing. For example, thick film printing includes a series of steps whereby a ceramic substrate is step-wise patterned and layered to form a complete heater. Instances of the process include layering a leveled-paste through a pattern, settling the paste, drying it, and firing or heating thereafter. As shorthand from the industry, the steps are generally known as print, dry, and fire, or PDF.

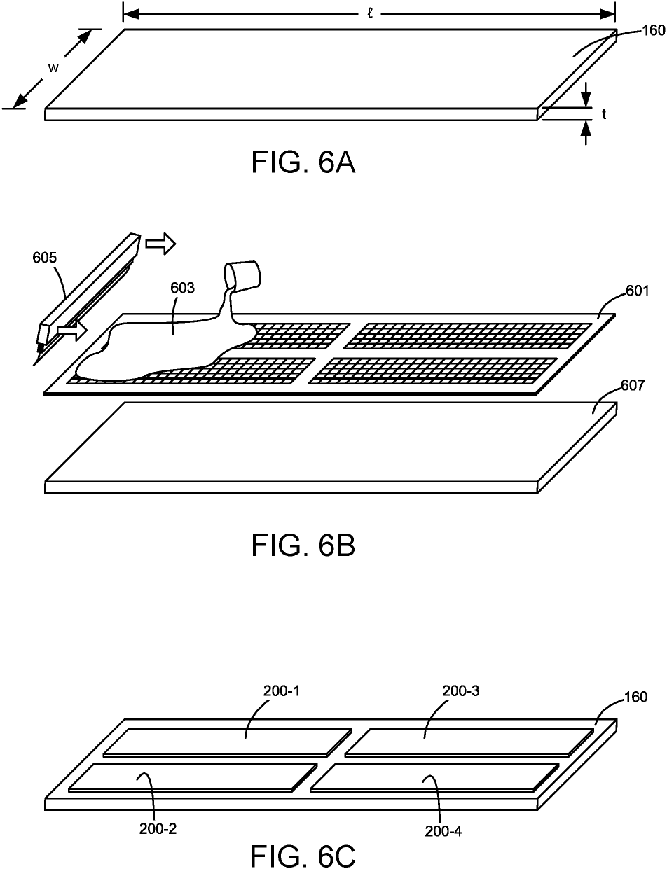

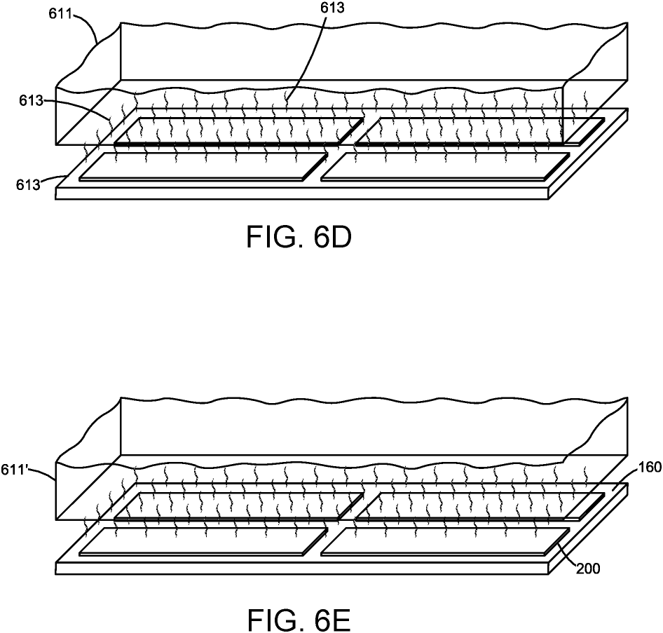

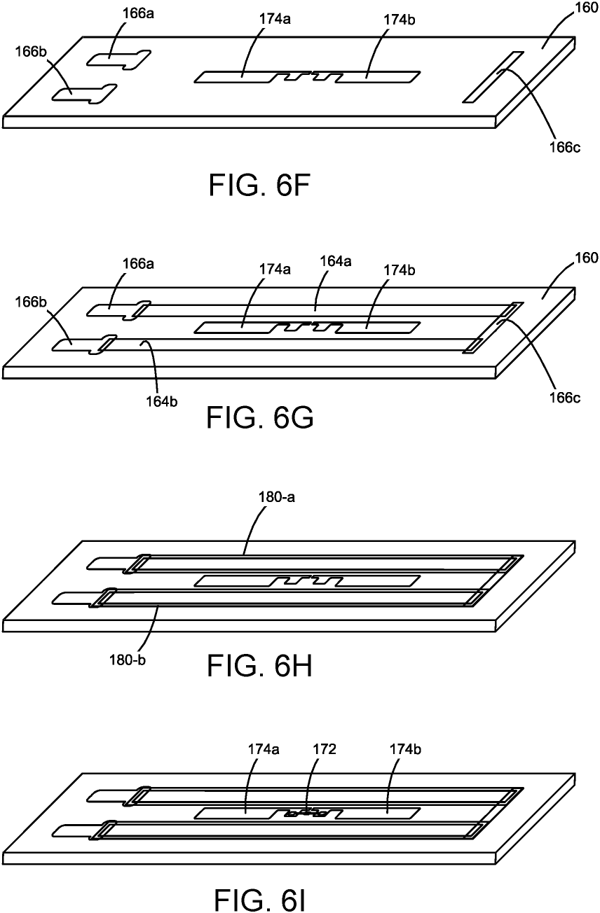

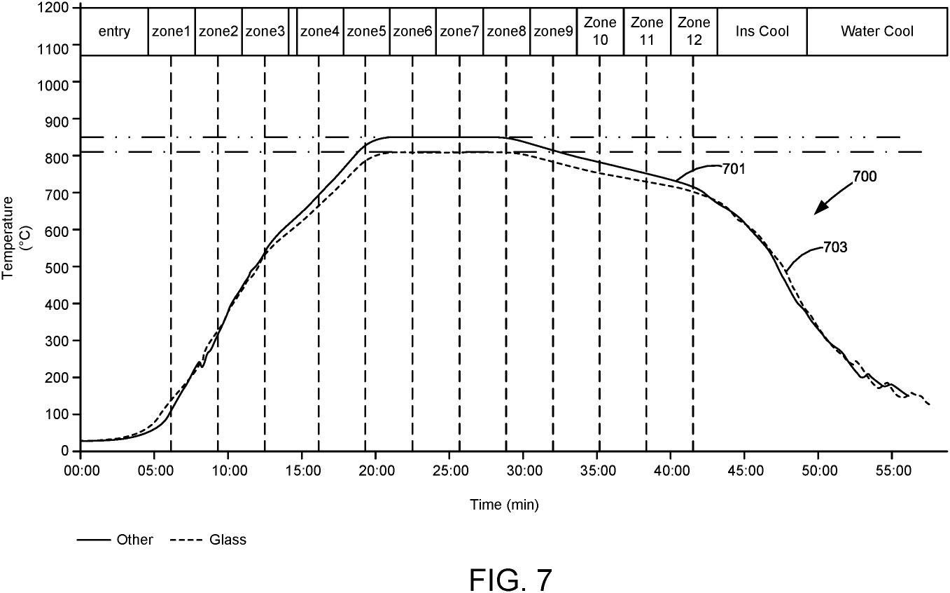

In more detail, FIGS. 6A-6F show the printing, drying, and firing. In FIG. 6A, a base or substrate, such as the aforementioned alumina substrate 160, is provided. In FIG. 6B, thick-film printing of the substrate includes providing a mesh stencil 601 upon and through which a paste 603 is applied. In the instance of layering a resistor, conductor or glass, a resistive paste, a conductive paste, or a glass paste is applied instead. Similarly, a metal paste is applied when layering a heat-spreader layer on a backside of the substrate. A leveling device 605, such as a squeegee or other scraper, levels the paste onto a surface 607 of the base. In FIG. 6C, the paste so applied is allowed to settle on the base forming a layer upon removal of the stencil, the layer could be the silver layer 200, in one or two applications. The settling occurs typically for about five to ten minutes at room temperature, e.g., 20° - 25° C. In FIG. 6D, the base and silver layer is then provided to a curing or drying unit 611. The drying unit typifies a box oven or blast furnace and the base is provided to the unit along a conveyor, typically. The drying unit begins drying the layer at around room temperature followed by a curing or drying cycle of about 30 minutes reaching temperatures of 140°- 160° C. In one embodiment, the drying cycle includes applying infrared heat or hot air (both given generically as heat 613) for a period of time of about 30 total minutes at a temperature profile of the drying unit beginning at about 25° C. and ramping up to about 80° C. for about 10 minutes, ramping up again to about 160° C. for about 10 minutes and cooling down to below 50° C. After that, the base with layer is fired in a heater or firing unit 611′, FIG. 6E. In some instances, the firing unit is the same unit as the drying unit 611, but having different heating profiles. In others, the firing unit is different from the drying unit 80 and the base advances from one unit to the next along a conveyor, typically. In any, the heating profile for heating the base depends upon which type of layer is most recently printed and dried thereon, e.g., silver layer, resistive layer, conductive layer, or glass layer. For the silver layer 200, the heating profile 700 is noted in FIG. 7 and includes profile 701 heating up to 850° C., maximum, over the course of an hour, whereby about 40 total minutes the heating profile starts at about 25° C. and ramps up to a peak temperature (part of zones 5-8) by 20 minutes and maintaining the peak temperature for at least 10 minutes and decreasing the temperature of the heating unit (post zone 8) for at least 10 minutes thereafter. Cooling continues even further thereafter (post zone 12) until completely cooled. The heating profile 703 is also similar for resistive and conductive layers. The profile 703 is noted for layering glass on the substrate.

Returning to FIG. 6F, on a side of the substrate 160 opposite the silver layer, conductive traces 166a, b, c, and 174a, 174b are printed on ceramic substrate 160, which includes selectively applying a paste containing conductor material in the same manner as the silver layer. The ceramic substrate 160 having the printed conductor is then allowed to settle, dried and fired in the same manner (FIGS. 6B-6E) as discussed above with respect to the silver to permanently affix the conductive traces in position. In FIG. 6G, the resistive traces 164 a, b are printed, dried, and fired on the ceramic substrate 160. Glass layer(s) 180-a, -b are then printed over the resistive traces, dried, and fired in FIG. 6H in substantially the same manner as the silver, conductors, and resistor, including allowing the glass layer(s) 180 to settle as well as drying and firing the glass layer(s) 180 according to heating profile 703, FIG. 7. Thermistor 172 in FIG. 6I is then mounted to ceramic substrate 160 in a finishing operation with the terminals of thermistor 172 directly welded to conductive traces 174a, 174b.

In various embodiments, the dimensions of the thickness of the resistive trace is about 10 - 13 µm on the base with a length of about 135 - 145 mm and a width of about 4.5 - 5.5 mm. Its resistance is about 10 - 12 ohms at 195° C. and formed from a resistor paste of about 80% silver and 20% palladium. The conductor in contrast has thicknesses of about 9 - 15 µm on the base substrate with a length of about 11 - 13 mm and a width of about 4.8 - 5.8 mm. Also, the conductor is formed from a conductive paste of silver and palladium or platinum. In one embodiment, pastes for conductor layers include content of about 93% silver and about 7% palladium or platinum. Other embodiments use about 99% silver and about 1% palladium or platinum.

The glasses 180 herein are noted as overlying an entirety of each resistive trace and at least a portion of the conductor, but not an entirety of the conductor as it needs to connect to the external power source. The glass may be singular, or multi-layered. The glass is any of a variety but may define a cross glass layer or cover glass layer. Viscosity of the glass is noted as representatively 100 Pa · s or less, more particularly at 90 Pa · s or less, especially 65 Pa · s or less. Its solid content representatively exists at 65% or more. The dimensions on the substrate include a thickness in a range of about 10 - 13 µm, a length in a range of about 135 - 145 mm, and a width in a range of about 4.5 - 5.5 mm.

Thick film printing resistive traces 164 and conductive traces 166 on fired ceramic substrate 160 provides more uniform resistive and conductive traces in comparison with conventional ceramic heaters, which include resistive and conductive traces printed on green state ceramic. The improved uniformity of resistive traces 164 and conductive traces 166 allows for more uniform heating across contact surface 118 as well as more predictable heating of heater 130.

Preferably, heaters 130/132 are produced in an array for cost efficiency. Heaters are separated into individual heaters 130/132 after the construction of all heaters is completed, including firing of all components and any applicable finishing operations. In some embodiments, individual heaters are separated from the array by way of fiber laser scribing. Fiber laser scribing tends to provide a more uniform singulation surface having fewer microcracks along the separated edge in comparison with conventional carbon dioxide laser scribing.

It will be appreciated that the example embodiments illustrated and discussed above are not exhaustive and that the heater of the present disclosure may include resistive and conductive traces in many different geometries, including resistive traces on the outer face and/or the inner face of the heater, as desired. Other components (e.g., a thermistor) may be positioned on either the outer face or the inner face of the heater as desired.

The present disclosure does, however, provide a ceramic heater having a low thermal mass in comparison with the heaters of conventional hair irons. In particular, thick film printed resistive traces on an exterior face (outer or inner) of the ceramic substrate provides reduced thermal mass in comparison with resistive traces positioned internally between multiple sheets of ceramic. The use of a thin film, thermally conductive sleeve, such as a polyimide sleeve) also provides reduced thermal mass in comparison with metal holders, guides, etc. The low thermal mass of the ceramic heater of the present disclosure allows the heater, in some embodiments, to heat to an effective temperature for use in a matter of seconds (e.g., less than five seconds), significantly faster than conventional hair irons. The low thermal mass of the ceramic heater of the present disclosure also allows the heater, in some embodiments, to cool to a safe temperature after use in a matter of seconds (e.g., less than five seconds), again, significantly faster than conventional hair irons.

Further, embodiments of the hair iron of the present disclosure operate at a more precise and more uniform temperature than conventional hair irons because of the closed loop temperature control provided by the thermistor in combination with the relatively uniform thick film printed resistive and conductive traces. The low thermal mass of the ceramic heater and improved temperature control permit greater energy efficiency in comparison with conventional hair irons. The rapid warmup and cooldown times of the ceramic heater of the present disclosure also provide increased safety by reducing the amount of time the hair iron is hot but unused. The improved temperature control and temperature uniformity further increase safety by reducing the occurrence of overheating. The improved temperature control and temperature uniformity also improve the performance of the hair iron of the present disclosure.

Observations of the inventors have noted that silver in thicknesses of 10-30 um work better under the conditions tested, and may be printed in singular or multiple steps. Thick-film printed silver as a heat-spreader is superior because of its intimate contact with the ceramic substrate, as compared to external heat spreaders having been adhesively attached. It is noted too that direct printing of the silver results in a higher thermal conductivity between the silver and the ceramic substrate. As silver has comparatively high thermal conductivity, compared to other metals (419 w/mK), silver makes a great selection, but other printed materials are also possible, such as pure or alloyed compositions of copper and aluminum.

Test Results. Heaters of the type described above were tested with two silver patterns and two thicknesses. Sample Type A: One rectangular pattern printed on the back side of the ceramic and covering over 90% of the entire ceramic substrate area of the heater. Type A was double printed with a total thickness of approximately 24 um. Sample Type B: Two rectangular patterns printed on the back side of the ceramic and covering the entire resistor length and width, with an addition of approximately 20% more area than the combined resistor area. Type B was single printed with a total thickness of approximately 12 um. Hair tresses were then positioned within the arms of the hair iron such that a small gap (about 2 mm) existed between the edges of the tress and each thermocouple. The test was designed to purposely create the highest thermal gradients possible under abnormal and non-recommended conditions of use. The highest setting of the hair iron was used (210° C.) and is higher than advised for either of the two hair types used in this trial. The speed of maneuvering the hair iron to straighten the hair tresses was also purposely slower than would be recommended. The unit was marked and great care was taken to repeat the trials in an abnormal way, such that the same width of hair repeatedly entered and exited the hair iron to purposely increase the temperature at the edges - where the thermocouples were monitoring temperatures. Under normal (and recommended) use conditions, these results are not expected. The results show a significant difference in maximum temperature between the hair irons having ceramic heaters with no silver thick-film printed and hair irons containing ceramic heaters with the thick film printed silver as described in the embodiments. As has been discovered, the latter hair irons have been observed to have maximum temperatures near the edges of the heaters that is lower by about 35° C. as compared to the former hair irons. It has also been observed that a particularly useful embodiment is that whereby the silver 200 has a thickness of about 24 µm.

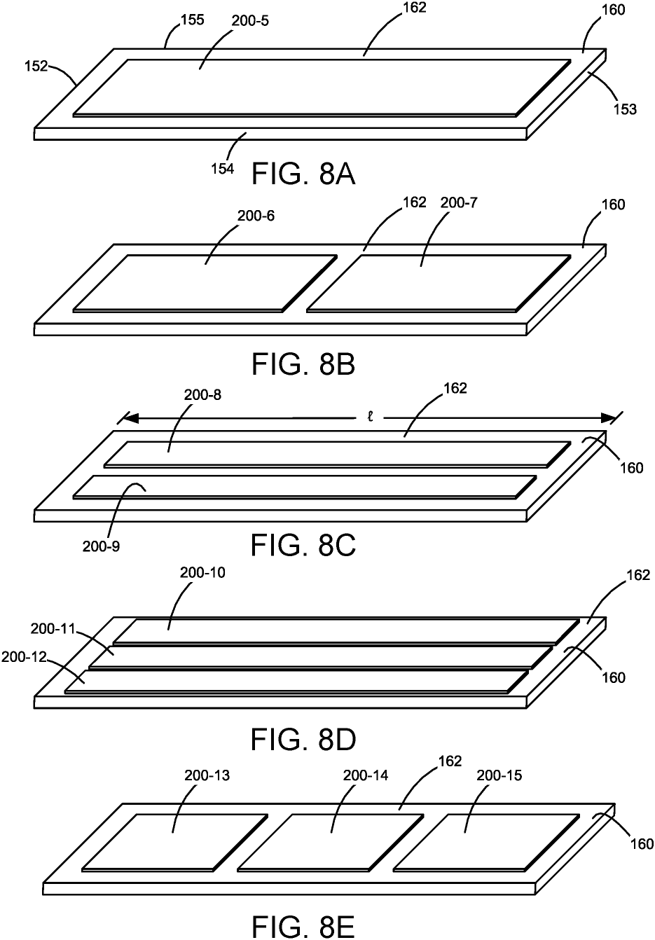

In FIGS. 8A-8E, various further embodiments of a metal, e.g., silver 200, thick-film printed in thicknesses from 10-30 µm on a substrate 160 are described. In FIG. 8A, the silver 200-5 is a singular rectangular patch of silver covering a surface area of about 80-95% of the outer face 162 of the substrate. Sides of the silver generally parallel edges 152, 153, 154, 155 of the substrate. In FIG. 8B, the silver 200-6, 200-7 is bifurcated into two large square-like patches covering similar surface area and being generally parallel between sides of the silver and edges of the substrate. In FIG. 8C, the silver 200-8, 200-9 is generally lengthwise along the outer face of the substrate and separated as two rectangular patches. In FIGS. 8D and 8E, three patches of silver 200 are disposed on the outer face of the substrate. In FIG. 8D, the patches 200-10, 200-11, 200-12 are generally lengthwise and parallel to one another and edges of the substrate. In FIG. 8E, the patches 200-13, 200-14, 200-15 are more square-like in orientation. Of course, other embodiments are possible, especially in numbers of patches, orientations, and shapes of the patches, including irregular or random shapes, and coverage area of the patches.

The foregoing description illustrates various aspects of the present disclosure. It is not intended to be exhaustive. Rather, it is chosen to illustrate the principles of the present disclosure and its practical application to enable one of ordinary skill in the art to utilize the present disclosure, including its various modifications that naturally follow. All modifications and variations are contemplated within the scope of the present disclosure as determined by the appended claims. Relatively apparent modifications include combining one or more features of various embodiments with features of other embodiments.

1. A hair iron, comprising:
a first arm and a second arm movable relative to each other between an open position and a closed position;
one or both of the first and second arms having a heater for heating hair placed between the first and second arms during use, wherein
the heater includes a ceramic substrate having a resistive trace for heating upon connection to power, and
on a side of the ceramic substrate opposite the resistive trace, a layer of silver.

2. The hair iron of claim 1, wherein the layer of silver is a composition of silver and platinum.

3. The hair iron of claim 2, wherein the composition is about 80% silver and about 20% platinum.

4. The hair iron of claim 1, wherein the layer of silver covers the side of the ceramic substrate in a range of about 80% to about 95% of a surface area of said side.

5. The hair iron of claim 1, wherein the layer of silver includes two layers of silver.

6. The hair iron of claim 5, wherein each layer of the two layers of silver includes a thickness of about 10 to about 20 µm.

7. The hair iron of claim 1, wherein a thickness of the layer of silver ranges from about 10 to about 30 µm.

8. The hair iron of claim 1, wherein the silver defines one or more patches of silver.

9. The hair iron of claim 8, wherein the one or more patches of silver have pluralities of sides paralleling pluralities of edges of the ceramic substrate.

10. The hair iron of claim 1, wherein the side of the ceramic substrate has a rectangular planar shape, wherein the layer of silver defines two or more rectangular patches of silver on said side.

11. The hair iron of claim 10, wherein the layer of silver defines three rectangular patches of silver on said side.

12. The hair iron of claim 10, wherein the layer of silver defines four rectangular patches of silver on said side.

13. The hair iron of claim 12, wherein each patch of the four rectangular patches has pluralities of sides paralleling pluralities of edges of the ceramic substrate.

14. The hair iron of claim 1, wherein the side of the ceramic substrate has a rectangular planar shape, wherein the layer of silver defines one or more squares of silver on said side.

15. A hair iron, comprising:
a first arm and a second arm movable relative to each other between an open position and a closed position; and
on both of the first and second arms, a heater for heating hair placed between the first and second arms during use, wherein the heater further includes
a ceramic substrate having on a first side two resistive traces for heating the hair upon connection to power, and
on a second side of the ceramic substrate opposite the first side, a layer of silver, wherein the layer of silver defines four rectangular patches of silver on said second side.

16. The hair iron of claim 15, wherein each patch of the four rectangular patches has pluralities of sides paralleling pluralities of edges of the ceramic substrate.

17. The hair iron of claim 15, wherein the layer of silver covers the second side of the ceramic substrate in a range of about 80% to about 95% of a surface area of said second side.

18. The hair iron of claim 15, wherein the layer of silver includes two layers of silver.

19. The hair iron of claim 18, wherein each layer of the two layers of silver includes a thickness of about 10 to about 20 µm.

20. The hair iron of claim 15, wherein a thickness of the layer of silver ranges from about 10 to about 30 µm.
